(19) United States
(12) Patent Application Publication
(10) Pub. No.: US 2026/0301830 A1
(43) Pub. Date: Oct. 1, 2026

(54) MEMORY DEVICE AND STORAGE DEVICE INCLUDING THE MEMORY DEVICE

(71) Applicant: SK hynix Inc., Icheon-si Gyeonggi-do (KR)

(72) Inventor: Won Hee LEE, Icheon-si Gyeonggi-do (KR)

(73) Assignee: SK hynix Inc., Icheon-si Gyeonggi-do (KR)

(21) Appl. No.: 19/373,148

(22) Filed: Oct. 29, 2025

(30) Foreign Application Priority Data
Mar. 27, 2025 (KR) 10-2025-0039504

(51) Int. Cl. G11C 16/34; G11C 16/08; G11C 16/26; G11C 16/32

(52) U.S. Cl. CPC G11C 16/3459; G11C 16/08; G11C 16/26; G11C 16/32

(57) ABSTRACT

A memory device includes a memory cell array including a first memory cell coupled to a first bit line and a second memory cell coupled to a second bit line; a peripheral circuit including a first page buffer coupled to the first memory cell via the first bit line; a second page buffer coupled to the second memory cell via the second bit line; and a control logic circuit configured to control the peripheral circuit. The second memory cell is positioned farther from a reference position than the first memory cell in a direction. The first page buffer is configured to perform a sensing operation or a double-verify program operation on the first memory cell during a first time period. The second page buffer is configured to perform a sensing operation or a double-verify program operation on the second memory cell during a second time period.

### CROSS REFERENCE TO RELATED APPLICATION

The present application claims priority under 35 U.S.C. §119(a) to Korean patent application number 10-2025-0039504 filed on Mar. 27, 2025, in the Korean Intellectual Property Office, the entire contents of which application is incorporated herein by reference.

### BACKGROUND

### 1. Technical Field

The present disclosure generally relates to a memory device and a storage device including the memory device, including but not limited to memory devices that perform a sensing operation and a double-verify program operation.

### 2. Related Art

Memory devices store data in response to a write request and output the stored data in response to a read request. For example, memory devices are classified as volatile memory devices, such as a Dynamic Random Access Memory (DRAM) device, a Static RAM (SRAM) device, and the like, which do not retain stored data when supplied power is interrupted, and non-volatile memory devices, such as a flash memory device, a Phase-change RAM (PRAM) device, a Magnetic RAM (MRAM) device, a Resistive RAM (RRAM) device, and the like, that retain stored data without supplied power or when supplied power is interrupted.

Memory devices are formed in a two-dimensional structure with strings arranged horizontally over a semiconductor substrate or in a three-dimensional structure with strings stacked vertically over a semiconductor substrate. Three-dimensional memory devices are designed to solve the limitations of integration density of two-dimensional memory devices and include a plurality of memory cells stacked vertically over a semiconductor substrate.

The memory cells may receive signals at different speeds depending on the structure of the memory device. The non-uniform speed may reduce the reliability and durability of the memory device.

### SUMMARY

According to an embodiment of the present disclosure, a memory device may include a memory cell array including a first memory cell coupled to a first bit line extending in a first direction and a second memory cell coupled to a second bit line extending in the first direction; a peripheral circuit including a first page buffer coupled to the first memory cell via the first bit line and a second page buffer coupled to the second memory cell via the second bit line; and a control logic circuit configured to control the peripheral circuit; wherein the second memory cell is positioned farther from a reference position than the first memory cell in a second direction perpendicular to the first direction; and wherein the first page buffer is configured to perform one of a sensing operation and a double-verify program operation on the first memory cell during a first time period, and the second page buffer is configured to perform one of a sensing operation and a double-verify program operation on the second memory cell during a second time period that has a different length than the first time period.

According to an embodiment of the present disclosure, a memory device may include a memory cell array including a first a first memory cell and a third memory cell coupled to a first bit line extending in a first direction, and a second memory cell and a fourth memory cell coupled to a second bit line extending in the first direction, the first memory cell and the second memory cell coupled to a first word line extending in a second direction perpendicular to the first direction, the third memory cell and the fourth memory cell coupled to a second word line extending in the second direction; a peripheral circuit including a first page buffer coupled to the first memory cell and the third memory cell via the first bit line, and a second page buffer coupled to the second memory cell and the fourth memory cell via the second bit line; and a control logic circuit configured to control the peripheral circuit, wherein the second memory cell and the fourth memory cell are positioned farther from a first reference position in the second direction than the first memory cell and the third memory cell are positioned relative to the first reference position in the second direction, wherein the first memory cell and the second memory cell are positioned farther from a second reference position in the first direction than the third memory cell and the fourth memory cells are positioned relative to the second reference position in the first direction, and wherein the first page buffer and the second page buffer are configured to perform one of a sensing operation and a double-verify program operation on the first memory cell, the second memory cell, the third memory cell, and the fourth memory cell during one of a plurality of time periods, each time period having a different length.

According to an embodiment of the present disclosure, a storage device may include a memory device configured to perform a read operation and a program operation; and a memory controller configured to control the memory device. The memory device may include a memory cell array including a first memory cell coupled to first bit line extending in a first direction and a second memory cell coupled to a second bit line extending in the first direction; a peripheral circuit including a first page buffer coupled to the first memory cell via the first bit line and a second page buffer coupled to the second memory cell via the second bit line; and a control logic circuit configured to control the peripheral circuit; wherein the second memory cell is positioned farther from a reference position in a second direction perpendicular to the first direction than the first memory cell is positioned relative to the reference position in the second direction, and wherein the first page buffer and the second page buffer are configured to perform one of a sensing operation and a double-verify program operation on the first memory cell and the second memory cell during one of a plurality of time periods, each time period having a different length.

### BRIEF DESCRIPTION OF THE DRAWINGS

FIG. 1 is a block diagram of a storage device according to an embodiment of the present disclosure;

FIG. 2 is a block diagram of a memory device according to an embodiment of the present disclosure;

FIG. 3 is a diagram of a structure of a memory block according to an embodiment of the present disclosure;

FIG. 4 is a diagram illustrating memory cells positioned at different distances from a reference position, according to an embodiment of the present disclosure;

FIG. 5 is a diagram of a page buffer according to an embodiment of the present disclosure;

FIG. 6 is a timing diagram of a sensing operation according to an embodiment of the present disclosure;

FIG. 7 is a timing diagram of threshold voltages according to an embodiment of the present disclosure;

FIG. 8 is a timing diagram of a double-verify program operation according to an embodiment of the present disclosure;

FIG. 9 is a diagram of a structure of a memory device according to an embodiment of the present disclosure;

FIG. 10 is a diagram of memory cells coupled to different word lines and positioned at different distances from a reference position according to an embodiment of the present disclosure;

FIG. 11 is a timing diagram of a sensing operation according to an embodiment of the present disclosure;

FIG. 12 is a timing diagram of threshold voltages according to an embodiment of the present disclosure;

FIG. 13 is a timing diagram of a double-verify program operation according to an embodiment of the present disclosure;

FIG. 14 is a block diagram of a memory card system including a storage device according to an embodiment of the present disclosure; and

FIG. 15 is a block diagram of an electronic system according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example.

When one element is identified as “coupled” to another element, the elements may be coupled directly or through at least one intervening element between the elements. When two elements are identified as “directly coupled,” one element is directly coupled to the other element without an intervening element between the two elements.

Terms such as “vertical,” “horizontal,” “bottom,” “over,” “overlap,” “on,” “outside,” “upper,” “uppermost,” “lower,” “lowermost,” “upward,” “downward,” “higher,” “low,” “right,” “column,” “row,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

The present disclosure is directed to a memory device that performs a sensing operation and a double-verify program operation, and a storage device including the memory device.

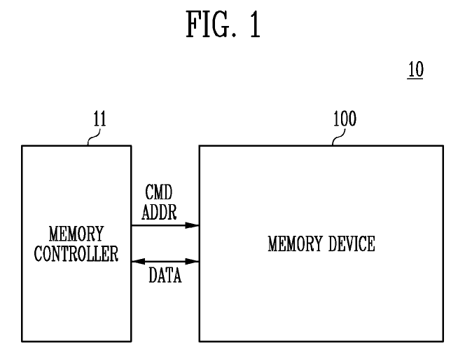

FIG. 1 is a block diagram of a storage device 10 according to an embodiment of the present disclosure. Referring to FIG. 1, the storage device 10 stores data. The storage device 10 may include at least one of a solid-state device (SSD), embedded memory, or removable external memory. When the storage device 10 is an SSD, the storage device 10 may be a device that conforms to Non-Volatile Memory express (NVMe) standards. When the storage device 10 is embedded memory or removable external memory, the storage device 10 may be a device that conforms to the Universal Flash Storage (UFS) or embedded Multi-Media Card (eMMC) standards.

The storage device 10 includes a memory controller 11 and a memory device 100. The memory controller 11 controls operations of the storage device 10. For example, the memory controller 11 controls operations of the storage device 10 in accordance with an internal policy, stored instructions, or in response to a request from an external host device. The memory controller 11 stores data in the memory device 100 or reads data stored in the memory device 100 in accordance with the internal policy, stored instructions, or in response to a request from the external host device. The memory controller 11 provides a command CMD and an address ADDR to the memory device 100 and sends and receive data DATA to and from the memory device 100.

The memory device 100 stores data under control of the memory controller 11. For example, the memory device 100 stores the data DATA or reads and provides the stored DATA to the memory controller 11 based on the command CMD and the address ADDR received from the memory controller 11.

The memory device 100 may be a non-volatile memory device, such as a NAND Flash memory device, although the present disclosure is not limited to this example. The memory device 100 may be one of various devices that retain stored data without supplied power or when supplied power is interrupted, such as a Phase-change Random Access Memory (PRAM) device, a Magnetic Random Access Memory (MRAM) device, a Resistive Random Access Memory (RRAM) device, a Ferroelectric Random Access Memory (FRAM) device, and the like.

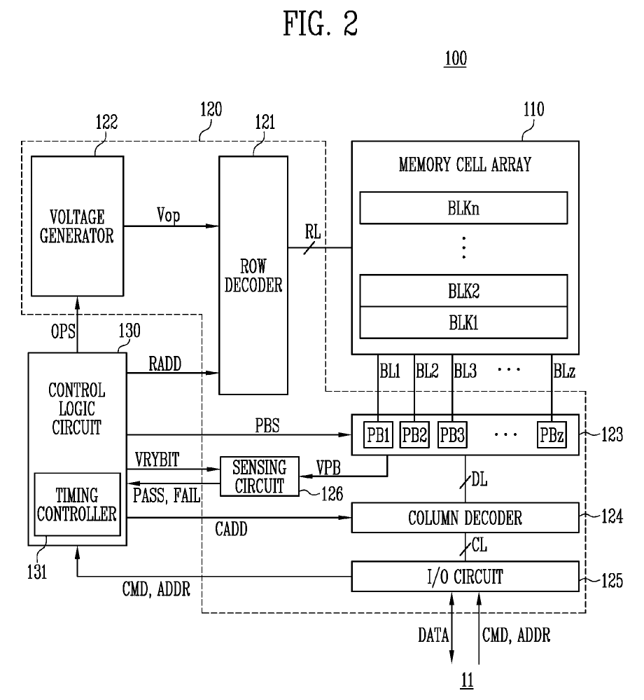

FIG. 2 is a block diagram of the memory device 100 according to an embodiment of the present disclosure. Referring to FIG. 2, the memory device 100 includes a memory cell array 110, a peripheral circuit 120, and a control logic circuit 130.

The memory cell array 110 includes a plurality of memory blocks BLK1 to BLKn. The plurality of memory blocks BLK1 to BLKn each include a plurality of memory cells and may be implemented in a two-dimensional structure in which memory cells are arranged parallel to a substrate or in a three-dimensional structure in which memory cells are stacked perpendicular to the substrate, where n is a positive integer.

The peripheral circuit 120 include a row decoder 121, a voltage generator 122, a page buffer circuit 123, a column decoder 124, an input/output I/O circuit 125, and a sensing circuit 126.

The row decoder 121 selects one memory block of the plurality of memory blocks BLK1 to BLKn in the memory cell array 110 based on a row address RADD and transfers operating voltages Vop to the selected memory block.

The row decoder 121 is coupled to the memory cell array via row lines RL. The row lines RL include first and second select lines, and a plurality of word lines arranged between the first and second select lines. The row lines RL may include dummy lines arranged between the first select line and the plurality of word lines and between the second select line and the plurality of word lines. The first select line is a source select line, and the second select line is a drain select line.

The row decoder 121 selects one of the row lines RL based on the row address RADD and transfers the operating voltages Vop to a memory block or a memory cell coupled to the selected row line RL. The operating voltages Vop include a program voltage, a verify voltage, a read voltage, a pass voltage, an erase voltage, and the like.

The voltage generator 122 generates and output the operating voltages Vop. For example, the voltage generator 122 generates and outputs the operating voltages Vop utilized for various operations in response to an operational signal OPS received from the control logic circuit 130. The voltage generator 122 outputs the generated operating voltages Vop to the plurality of memory blocks BLK1 to BLKn in the memory cell array 110 via the row decoder 121.

The page buffer circuit 123 is coupled to the memory cell array 110 via a plurality of bit lines BL1 to BLz. The page buffer circuit 123 includes a plurality of page buffers PB1 to PBz coupled to the plurality of bit lines BL1 to BLz, respectively. The plurality of page buffers PB1 to PBz operates in response to a page buffer control signal PBS and temporarily stores data during a program operation or a read operation, where z is a positive integer.

The plurality of page buffers PB1 to PBz sense the plurality of bit lines BL1 to BLz during a read operation or a verify operation. For example, the plurality of page buffers PB1 to PBz sense voltages of the plurality of bit lines BL1 to BLz and compare the sensed voltages with threshold voltages of the memory cells coupled via the plurality of bit lines BL1 to BLz to perform a read operation or a verify operation on the memory cells.

The column decoder 124 transfers data between the page buffer circuit 123 and the I/O circuit 125 based on a column address CADD. For example, the column decoder 124 sends and receives data to and from the plurality of page buffers PB1 to PBz via data lines DL or sends and receives data to and from the I/O circuit 125 via column lines CL.

The I/O circuit 125 communicates with the memory controller 11 of FIG. 1. For example, the I/O circuit 125 receives the command CMD and the addresses ADDR from the memory controller 11 or an external device and sends and receives the data DATA. The I/O circuit 125 provides the received command CMD and the received address ADDR to the control logic circuit 130 and provides the data DATA to the column decoder 124 via the column lines CL. The I/O circuit 125 provides the data DATA received from the column decoder 124 to the memory controller 11 or the external device.

During a read operation or a verify operation, the sensing circuit 126 generates a reference current in response to an allowable bit VRYBIT and outputs a pass signal PASS or a fail signal FAIL in response to a comparison between a sensing voltage VPB received from the page buffer circuit 123 and a reference voltage generated by the reference current.

The control logic circuit 130 controls the peripheral circuit 120. For example, the control logic circuit 130 generates and outputs various signals to control the peripheral circuit 120. In an embodiment, the control logic circuit 130 outputs the operational signals OPS, the row address RADD, the allowable bit VRYBIT, the page buffer control signals PBS, and the column address CADD in response to the command CMD and the address ADDR.

The control logic circuit 130 includes software that performs an algorithm in response to the command CMD and hardware or a module configured to output various signals based on the address ADDR and the algorithm. For example, the control logic circuit 130 adjusts voltage levels of various signals included in the page buffer control signals PBS during a read operation or a verify operation.

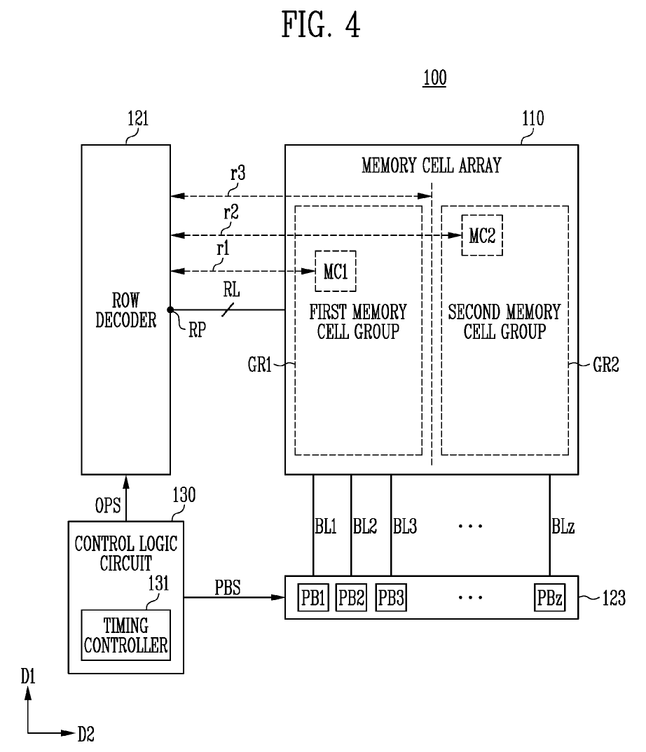

The control logic circuit 130 includes a timing controller 131. The timing controller 131 adjusts times at which the page buffer circuit 123 senses voltages on the plurality of bit lines BL1 to BLz and/or applies double-verify voltages to the plurality of bit lines BL1 to BLz. The timing controller 131 is described with reference to FIGS. 4, 6 to 9, and 12 to 14.

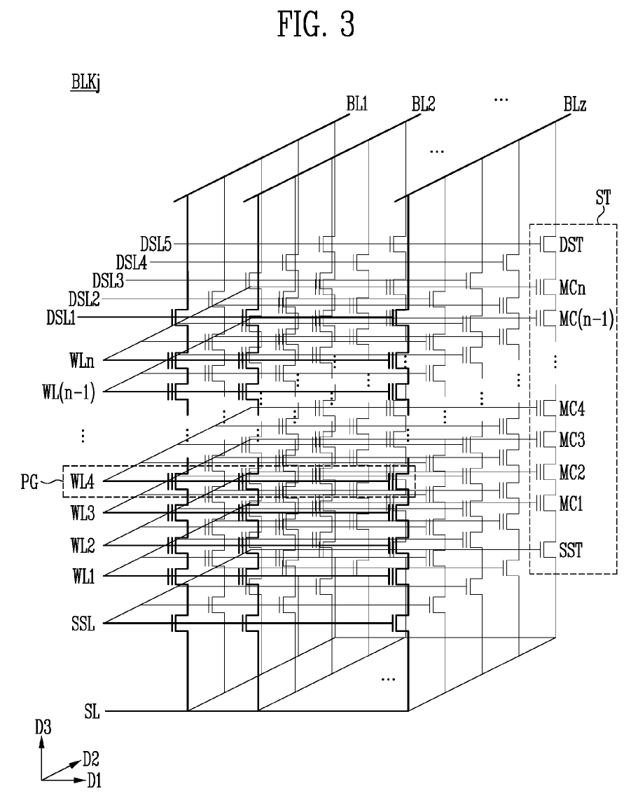

FIG. 3 is a diagram of a structure of a memory block according to an embodiment of the present disclosure. Referring to FIG. 3, a structure of a jth memory block BLKj of the plurality of memory blocks BLK1 to BLKn of FIG. 2 is illustrated, where j is a positive integer between 1 and n.

Because the plurality of memory blocks BLK1 to BLKn are configured in the same manner, the jth memory block BLKj is shown as an example. The jth memory block BLKj includes strings ST coupled between a source line SL and the bit lines BL1 to BLz. The strings ST are coupled in common to the source line SL, coupled in common to each of the bit lines BL1 to BLz, and coupled to each of the different bit lines BL1 to BLz. The strings ST are spaced apart from each other in a first direction D1 and a second direction D2 and extend in a third direction D3. The first to zth bit lines BL1 to BLz are spaced apart from each other in the first direction D1, and each of the bit lines BL1 to BLz extends in the second direction D2.

The quantity of source select transistors SST, first to nth memory cells MC1 to MCn, and drain select transistors DST included in each of the strings ST varies depending on the memory device. For example, although FIG. 3 illustrates each of the strings ST including one source select transistor SST and one drain select transistor DST, a plurality of source select transistors SST and a plurality of drain select transistors DST may be included in each of the strings ST.

Gates of the source select transistors SST in the different strings ST are coupled to source select lines SSL, gates of the memory cells MC1 to MCn in the different strings ST are coupled to word lines WL1 to WLn, and gates of the drain select transistors DST in the different strings ST are coupled to drain select lines DSL1 to DSL5, where n is a positive integer. Although five drain select lines, such as the drain select lines DSL1 to DSL5 are shown in FIG. 3 as an example, the quantity of drain select lines may vary and the present disclosure is not limited to this example.

The source select lines SSL are coupled in common to the source select transistors SST arranged in the first direction D1 and the second direction D2, although one or more of the source select lines SSL arranged in the second direction D2 are spaced apart. Each of the word lines WL1 to WLn are coupled in common to memory cells arranged in the first direction D1 and the second direction D2. For example, the nth memory cells MCn arranged in the first direction D1 or the second direction D2 are coupled in common to the nth word line WLn, and the nth word lines WLn are coupled to each other. For example, the (n-1) memory cells MC(n-1) arranged in the first direction D1 or the second direction D2 are coupled in common to the (n-1) word lines WL(n-1), and the (n-1) word lines WL(n-1) are coupled to each other. The nth word line WLn is spaced apart from the (n-1) word line WL(n-1). A group of memory cells coupled in common to one of the word lines WL1 to WLn is referred to a page PG. For example, the fourth memory cells MC4 coupled in common to the fourth word line WL4 is one page PG. A program operation is performed on units of pages PG. When the fourth word line WL4 is a selected word line, the word lines except for the selected word line are unselected word lines. The jth memory block BLKj includes as many pages PG as the quantity of the word lines WL1 to WLn.

In an embodiment, one memory cell stores one bit of data. A memory cell capable of storing one bit of data is typically referred to as a single-level cell (SLC). In this example, one page PG stores data corresponding to one logical page LPG. The data corresponding to one logical page LPG includes as many data bits as the quantity of memory cells included in one page PG.

In an embodiment, one memory cell may store two or more bits of data. A memory cell capable of storing two or more bits of data is referred to as a multi-level cell (MLC). In this example, one page PG stores data corresponding to two or more logical pages LPG.

FIG. 4 is a diagram illustrating memory cells positioned at different distances from a reference position, such as RP on one surface of the row decoder 121, according to an embodiment of the present disclosure. Referring to FIGS. 2 and 4, the memory cell array 110 includes a plurality of memory cells, including the first memory cell MC1 and the second memory cell MC2.

The memory cell array 110 receives the operating voltages Vop from the row decoder 121 via the row lines RL. For example, the first memory cell MC1 and the second memory cell MC2 receive the operating voltages Vop, such as a read voltage or a program voltage, from the row decoder 121 via the row lines RL. The row lines RL includes a plurality of word lines.

The first memory cell MC1 and the second memory cell MC2 are positioned at different distances from the row decoder 121. For example, the first memory cell MC1 is positioned at a first distance r1 in the second direction D2 from a reference position RP on one surface of the row decoder 121, and the second memory cell MC2 is positioned at a second distance r2 in the second direction D2 from the reference position RP. Different memory cells in the memory cell array 110 are coupled to the row decoder 121 via row lines RL having different lengths.

The first memory cell MC1 and the second memory cell MC2 are illustrated by way of example, and the memory cell array 110 may include other memory cells positioned at distances different from the distances r1 and r2 at which the memory cells MC1 and MC2 are respectively positioned from the reference position RP. For example, the memory cell array 110 includes a third memory cell at a fourth distance from the reference position RP.

In an embodiment, the memory cell array 110 includes a first memory cell group GR1 and a second memory cell group GR2. The first memory cell group GR1 includes the first memory cell MC1 and a plurality of memory cells and is positioned within a third distance r3 in the second direction D2 from the reference position RP. The second memory cell group GR2 includes the second memory cell MC2 and a plurality of memory cells and is positioned at a distance greater than the third distance r3 in the second direction D2 from the reference position RP. Bit lines coupled to the first memory cell group GR1 are referred to as a first bit line group, and bit lines coupled to the second memory cell group GR2 are referred to as a second bit line group.

The row lines RL may be conductors composed of one or more of various materials, such as poly-silicon, tungsten (W), titanium (Ti), tantalum (Ta), a tantalum nitride (TaN), silicide, copper (Cu), and aluminum (Al). The row lines RL may be low resistance conductors and may each have a resistance value proportional to their length.

In an more embodiment, when the first memory cell MC1 is positioned closer to the row decoder 121 or the reference position RP than the second memory cell MC2, such as when the first distance r1 is less than the second distance r2, the first memory cell MC1 is coupled to the row decoder 121 via the row line RL or a word line of a shorter length than the row line RL via which the second memory cell MC2 is coupled to the row decoder 121. The first memory cell MC1 receives the operating voltage Vop from the row decoder 121 via the row line RL having a lower resistance value than the row line RL coupled to the second memory cell MC2.

In an embodiment, a resistive component of the row lines RL coupled between the row decoder 121 and the memory cell array 110 causes a delay between a time at which the row decoder 121 outputs the operating voltage Vop and a time at which the memory cells receive the operating voltage Vop. For example, when the row decoder 121 outputs the operating voltage Vop to the first memory cell MC1 at a first time, the first memory cell MC1 receives the operating voltage Vop at a second time after a first time period has elapsed from the first time.

Receiving the operating voltage Vop from the row decoder 121 via the row line RL having a lower resistance value indicates, for example, a shorter delay caused due to the resistive component of the row line RL. For example, when the row decoder 121 outputs the operating voltage Vop via the row line RL to the first memory cell MC1 and the second memory cell MC2 at the first time, the first memory cell MC1 receives the operating voltage Vop at the second time after a first time period has elapsed from the first time, and the second memory cell MC2 receives the operating voltage Vop at a third time after a second time period, which is longer than the first time period, has elapsed from the first time. The first memory cell MC1 receives the operating voltage Vop from the row decoder 121 sooner or faster than the second memory cell MC2 receives the operating voltage Vop from the row decoder 121.

In an embodiment, the resistive component of the row lines RL causes a bias of threshold voltages during a read operation. For example, the resistive component of the row lines RL causes the threshold voltages to shift to different voltage levels, which threshold voltages the page buffer circuit 123 compares to the voltages sensed on the bit lines to read data from the memory cells.

The memory cells, such as MC1 and MC2, at different distances from the row decoder 121 or from the reference position RP receive the operating voltage Vop after different delays, and the threshold voltages shifting to different voltage levels may cause problems, such as reducing the reliability and durability of the memory device 100.

To ameliorate or reduce the problems caused by memory cells receiving the operating voltage Vop after different delays, the memory device 100 according to an embodiment performs sensing operations or double-verify program operations on memory cells, such as the memory cells MC1 and MC2, or memory cell groups, such as the memory cell groups GR1 and GR2, during time periods having different lengths and/or starting at different times.

The timing controller 131 adjusts times at which the page buffer circuit 123 senses the voltages on the plurality of bit lines BL1 to BLz or applies the double-verify voltages to the plurality of bit lines BL1 to BLz. The timing controller 131 adjusts a sensing time or double-verify time based on a position, such as the distance from the row decoder 121, or the reference position RP, or the length of the row line RL, of a memory cell that is a target of a read operation or program operation.

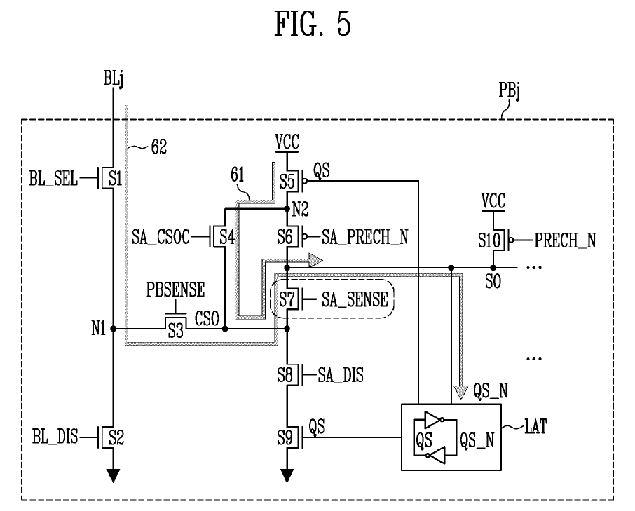

FIG. 5 is a diagram of a page buffer according to an embodiment of the present disclosure. Referring to FIGS. 2 and 5, because the plurality of page buffers PB1 to PBz is configured in a similar manner, a jth page buffer PBj of the plurality of page buffers PB1 to PBz is described as an example, where j is a positive integer between 1 and z.

The jth page buffer PBj includes a plurality of switches. FIG. 5 and the associated text describe a section of the jth page buffer PBj for simplicity.

The jth page buffer PBj includes a first switch S1 to a tenth switch S10 and a latch LAT. The jth page buffer PBj includes the plurality of latches LAT, although one latch LAT is shown in FIG. 5 for simplicity. Signals applied to the respective switches shown in FIG. 5 are included in the page buffer control signals PBS.

The latch LAT includes a main node QS where main data re stored, and an inverting node QS_N where inverted data of the main data, or inverted main data, are stored. The latch LAT includes a plurality of inverters.

The first switch S1 may be implemented with an N-type Metal-Oxide-Semiconductor (NMOS) transistor that is turned on or turned off in response to a bit line select signal BL_SEL. For example, when the first switch S1 is turned on, a voltage of a first node N1 is transferred to the jth bit line BLj, or a voltage or current of the jth bit line BLj is transferred to the first node N1. The second switch S2 may be implemented with an NMOS transistor that connects or disconnects the first node N1 to or from a ground terminal in response to a bit line discharge signal BL_DIS. For example, when the second switch S2 is turned on, the first node N1 is discharged.

The third switch S3 may be implemented with an NMOS transistor that connects or disconnects the first node N1 to or from a common sensing node CSO in response to a page buffer sensing signal PBSENSE. The fourth switch S4 may be implemented with an NMOS transistor that connects or disconnects the common sensing node CSO to or from a second node N2 in response to a common sensing signal SA_CSOC.

The fifth switch S5 may be implemented with a P-type Metal-Oxide-Semiconductor (PMOS) transistor that supplies a power voltage VCC to the second node N2 or blocks the supply of the power voltage VCC based on the data stored in the main node QS of the latch LAT. The sixth switch S6 may be implemented with a PMOS transistor that connects or disconnects the second node N2 to or from a sensing node SO in response to a sensing node precharge signal SA_PRECH_N. The seventh switch S7 may be implemented with an NMOS transistor that connects or disconnects the sensing node SO to or from the common sensing node CSO in response to a sensing signal SA_SENSE.

When the switches S4 and S5 are turned on, the power voltage VCC is supplied to the common sensing node CSO, thus the voltage level of the common sensing node CSO increases. When the switches S4, S5, and S7 are turned on during the same time interval, a current path 61 is formed through the switches S4, S5, and S7, such that the turn-on level of the switches S4, S5, and S7 affects the level of the voltage applied to the common sensing node CSO. For example, when the turn-on level of the seventh switch S7 is lower than the turn-on level of the switches S4 and S5, and the turn-on level of the seventh switch S7 increases, the amount of current flowing through the switches S4, S5, and S7 increases, resulting in an increase in voltage at the common sensing node CSO. When the turn-on level of the seventh switch S7 decreases, the amount of current flowing through the switches S4, S5, and S7 decreases, resulting in a decrease in the voltage at the common sensing node CSO. Thus, the voltage level at the common sensing node CSO may be adjusted during the sensing operation.

The eighth switch S8 and the ninth switch S9 discharge the common sensing node CSO according to a sensing node discharge signal SA_DIS and the data stored in the main node QS of the latch LAT. The eighth switch S8 is coupled between the common sensing node CSO and the ninth switch S9, and the ninth switch S9 is coupled between the eighth switch S8 and the ground terminal. The eighth switch S8 may be implemented with an NMOS transistor that is turned on or off in response to the sensing node discharge signal SA_DIS. The ninth switch S9 may be implemented with an NMOS transistor that may be turned on or off according to the data stored in the main node QS of the latch LAT. Thus, the common sensing node CSO is discharged when the eighth and ninth switches S8 and S9 are turned on during the same time interval.

The tenth switch S10 may be implemented with a PMOS transistor that supplies or blocks the power voltage VCC to the sensing node SO in response to a precharge signal PRECH_N.

The sensing node SO is coupled to the inverting node QS_N of the latch LAT. Thus, during the sensing operation, the voltage at the sensing node SO is transferred to the inverting node QS_N of the latch LAT.

The control logic circuit 130 of FIG. 2 provides the page buffer control signals PBS to the jth page buffer PBj to turn on or turn off the first to tenth switches.

In an embodiment, the control logic circuit 130 may turn on the switches S1 and S3 to S7 such that the power voltage VCC is applied to the jth bit line BLj during the precharge operation performed in the read operation. The control logic circuit 130 turns on the switches S1, S3, and S7 along a current path 62 such that the voltage on the jth bit line BLj is transferred to the latch LAT during the sensing operation performed in the read operation.

In an embodiment, the memory device 100 performs program operations during first to third program modes. During the program operation, different potentials maintained at the jth bit line BLj when the third switch S3 is turned on in response to the page buffer control signal PBS. During the first program mode, the voltage at the jth bit line BLj is maintained at a ground voltage. During the second program mode or program inhibition mode, the voltage at the jth bit line BLj is maintained at the power voltage VCC. During the third program mode or double-verify program operation that lowers the voltage at which data is programmed into the memory cell, the voltage at the jth bit line BLj is maintained between a ground voltage and the power voltage VCC.

In an embodiment, the control logic circuit 130 turns on the switches S1 and S3 to S7 such that, during the program operation in the third program mode, or the double-verify program mode, the power voltage VCC, the voltage level of which is adjusted, is transferred to the jth bit line BLj as a double-verify voltage.

The jth page buffer PBj includes a plurality of additional latches and a plurality of switches that transfer data between the plurality of latches.

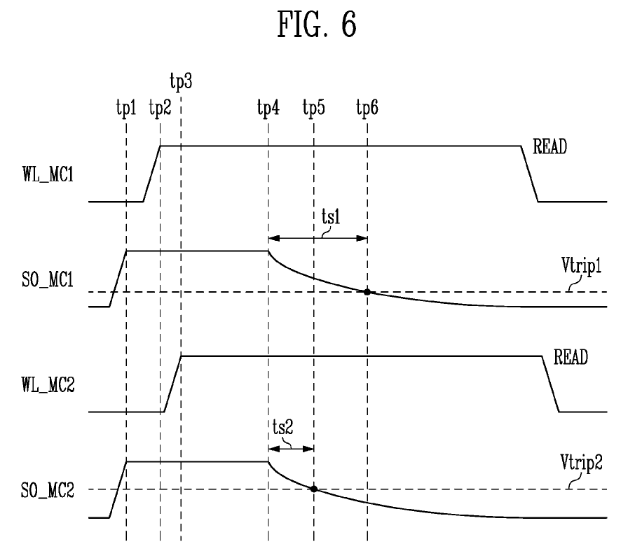

FIG. 6 is a timing diagram of a sensing operation according to an embodiment of the present disclosure. Referring to FIGS. 4 and 6, the control logic circuit 130 or the timing controller 131 adjusts the length of the sensing time period for the first memory cells MC1 to differ from the length of the sensing time period for the second memory cell MC2.

The memory cells MC1 and MC2 are positioned at different distances from the row decoder 121 or the reference position RP. For example, the first memory cell MC1 is at the first distance r1 from the reference position RP, and the second memory cell MC2 is at the second distance r2 that is longer than the first distance r1 from the reference position RP. When a read voltage is applied to the memory cells MC1 and MC2 coupled to one word line, the second memory cell MC2 receives the read voltage at a later time than the first memory cell MC1 receives the read voltage.

For example, the first memory cell MC1 is coupled to the first page buffer PB1 via the first bit line BL1, and the second memory cell MC2 is coupled to the second page buffer PB2 via the second bit line BL2. The first page buffer PB1 includes a first switch coupled between the first bit line BL1 and a first common sensing node, and a second switch coupled between the first common sensing node and a first sensing node SO_MC1. The second page buffer PB2 includes a third switch coupled between the second bit line BL2 and a second common sensing node, and a fourth switch coupled between the second common sensing node and a second sensing node SO_MC2.

At a first time tp1, the bit lines BL1 and BL2 are precharged, causing the voltage levels of the sensing nodes SO_MCb and SO_MC2 to rise. After the bit lines BL1 and BL2 are precharged, the row decoder 121 transfers a read voltage READ to the word lines coupled to the memory cells MC1 and MC2.

At a second time tp2, the read voltage READ is applied to the first memory cell MC1 via the word line. Because the first memory cell MC1 is positioned at a shorter distance from the row decoder 121 or the reference position RP than the second memory cell MC2, and because the first distance r1 is shorter than the second distance r2, the read voltage READ is applied first to the first memory cell MC1.

At a third time tp3, a read voltage READ is applied to the second memory cell MC2 via the word line.

In an embodiment, the page buffers PB1 and PB2 compare a first threshold voltage Vtrip1 and a second threshold voltage Vtrip2, having different values, with the voltages sensed on the bit lines BL1 and BL2 that are the voltages sensed on the first and second memory cells MC1 and MC2, respectively.

The control logic circuit 130 or the timing controller 131 adjusts the lengths of first sensing time period ts1 and the second sensing time period ts2 of the memory cells MC1 and MC2 when the first threshold voltages Vtrip1 has a different value than the second threshold voltage Vtrip2. For example, the control logic circuit 130 or the timing controller 131 adjusts the first sensing time period ts1 to be longer than the second sensing time period ts2 when the first threshold voltage Vtrip1 is lower than the second threshold voltage Vtrip2.

At a fourth time tp4, the voltage levels of the sensing nodes SO_MC1 and SO_MC2 begin to decrease as the bit lines BL1 and BL2 are discharged.

At a fifth time tp5 after the second sensing time period ts2 has elapsed from the fourth time tp4, the voltage on the second bit line BL2 is sensed. For example, the control logic circuit 130 senses the voltage on the second bit line BL2 by turning on the third switch coupled between the second bit line BL2 and the second common sensing node, and the fourth switch coupled between the second common sensing node and the second sensing node SO_MC2.

At a sixth time tp6 after the first sensing time period ts1 has elapsed from the fourth time tp4, the voltage on the first bit line BL1 is sensed. For example, the control logic circuit 130 senses the voltage on the first bit line BL1 by turning on the first switch coupled between the first bit line BL1 and the first common sensing node, and the second switch coupled between the first common sensing node and the first sensing node SO_MC1.

The first time tp1 to the sixth time tp6 are provided as examples for simplicity of description, and the control logic circuit 130 or the timing controller 131 may control the peripheral circuit 120 to apply voltages to a word line or bit lines at times other than the times tp1 to tp6.

The control logic circuit 130 or the timing controller 131 adjusts the lengths of the sensing times, f sensing time periods ts1 and ts2, to accurately sense memory cells, MC1 and MC2, at different distances from the row decoder 121 or the reference position RP.

Although FIG. 6 illustrates adjusting the sensing time periods ts1 and ts2 to sense the memory cells MC1 and MC2, the present disclosure is not limited to this example. For example, the control logic circuit 130 or the timing controller 131 may adjust a third sensing time period to be shorter than the sensing time periods ts1 and ts2 to sense a third memory cell positioned farther from the row decoder 121 or the reference position RP than the memory cells MC1 and MC2.

The control logic circuit 130 or the timing controller 131 adjusts the length of the sensing time period of each memory cell MC1 or MC2, as well as the sensing time period of a memory cell group including each memory cell such as memory cell group GR1 or GR2. For example, the sensing time period of the first memory cell group GR1 that is within the third distance r3 from the row decoder 121 or the reference position RP is adjusted to the first sensing time period ts1, and the sensing time period of the second memory cell group GR2 that is positioned at a distance greater than the third distance r3 from the row decoder 121 or the reference position RP is adjusted to the second sensing time period ts2.

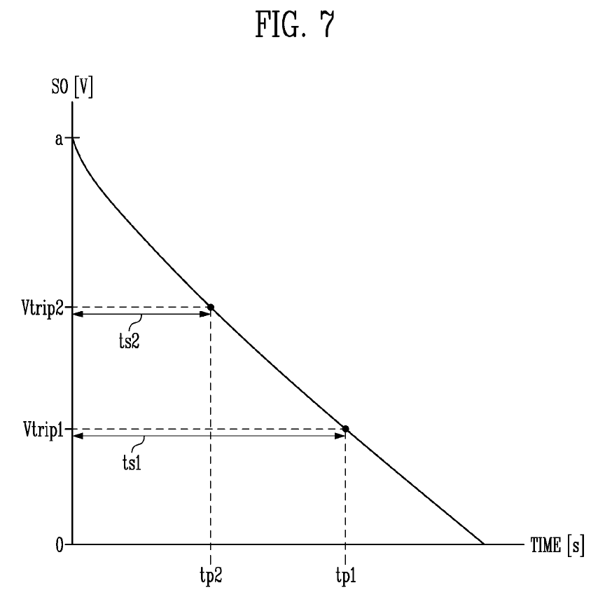

FIG. 7 is a timing diagram of the threshold voltages Vtrip1 and Vtrip2 according to an embodiment of the present disclosure. Referring to FIGS. 4 and 7, the page buffers PB1 and PB2 compare the threshold voltages Vtrip1 and Vtrip2 having different values with the voltages sensed on the bit lines BL1 and BL2.

The vertical axis of the graph indicates the voltage level at the sensing node SO, and the horizontal axis indicates the time after the time 0 at which the bit line is discharged for the sensing operation.

The page buffers PB1 and PB2 sense the voltages on the bit lines BL1 and BL2, and compare the sensed voltages with the threshold voltages Vtrip1 and Vtrip2, respectively, to read the data from the memory cells MC1 and MC2. The voltage levels of the threshold voltages Vtripb and Vtrip2 are different, although the speeds at which the bit lines BL1 and BL2 are discharged may be the same. Thus, the control logic circuit 130 or the timing controller 131 adjusts the lengths of the sensing time periods ts1 and ts2 such that the page buffers PB1 and PB2 may accurately read the data from the memory cells MC1 and MC2, respectively.

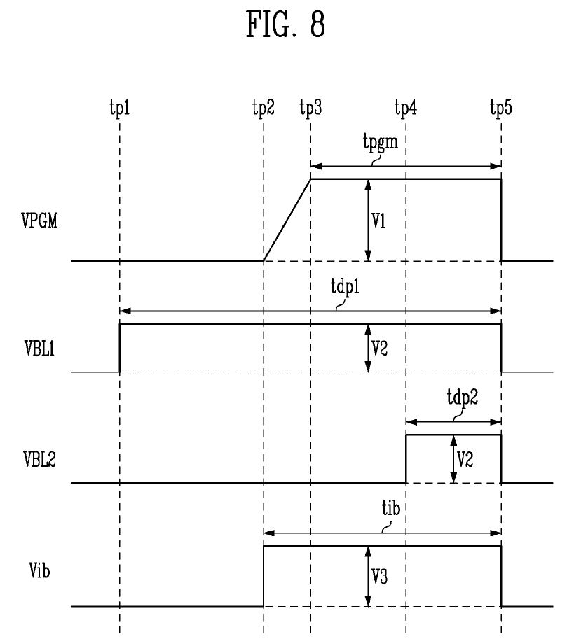

FIG. 8 is a timing diagram of a double-verify program operation according to an embodiment of the present disclosure. Referring to FIGS. 4 and 8, the control logic circuit 130 or the timing controller 131 adjusts the length of the double-verify program time of the first memory cells MC1 to differ from the length of the double-verify program time of the second memory cell MC2.

The page buffers PB1 and PB2 apply double-verify voltages to the bit lines BL1 and BL2 to which the memory cells MC1 and MC2 are coupled, respectively. For example, when the row decoder 121 transfers a program voltage through a word line to the memory cells MC1 and MC2, the page buffers PB1 and PB2 apply the double-verify voltages to the bit lines BL1 and BL2 to which the first and second memory cells MC1 and MC2 are coupled, respectively.

As described with reference to FIG. 5, the double-verify voltages have a lower voltage level than an inhibit voltage Vib. For example, when the double-verify voltage is at a second voltage level V2, the inhibit voltage Vib is at a third voltage level V3 that is higher than the second voltage level V2.

For example, the first memory cell MC1 is coupled to the first page buffer PB1 via the first bit line BL1, and the second memory cell MC2 is coupled to the second page buffer PB2 via the second bit line BL2. The first page buffer PB1 includes the first switch coupled between the first bit line BL1 and the first common sensing node, and the second switch coupled between the first common sensing node and the first sensing node SO_MC1. The second page buffer PB2 includes the third switch coupled between the second bit line BL2 and the second common sensing node, and the fourth switch coupled between the second common sensing node and the second sensing node SO_MC2.

At the first time tp1, the first page buffer PB1 applies a double-verify voltage at voltage V2 to the first bit line BL1 as VBL1. The control logic circuit 130 or the timing controller 131 applies the double-verify voltage to the first memory cell MC1 at the first distance r1 from the row decoder 121 or the reference position RP, where r1 is closer to the row decoder 121 or the reference position RP than the second memory cell MC2, earlier than providing the double-verify voltage to the second memory cell MC2 to prevent or mitigate abnormal distribution of right flying cells caused by the low resistance of the row line RL.

At the second time tp2, the page buffers except for the page buffers PB1 and PB2 apply the inhibit voltage Vib at voltage V3 to unselected bit lines for a time period tib.

At the third time tp3, the row decoder 121 applies a program voltage VPGM at voltage V1 to the memory cells MC1 and MC2 via word lines for a time period tpgm.

At the fourth time tp4, the second page buffer PB2 applies the double-verify voltage at voltage V2 to the second bit line BL2 as VBL2. The control logic circuit 130 or the timing controller 131 applies the double-verify voltage to the second memory cell MC2 located at the second distance r2 from the row decoder 121 or the reference position RP, that is farther from the row decoder 121 or the reference position RP than the first memory cell MCb is located, at a later time than the double-verify voltage is applied to the first memory cell MC1.

The first page buffer PB1 applies the double-verify voltage at voltage V2 to the first bit line BL1 during a first time period tdp1 between the first time tp1 and the fifth time tp5, and the second page buffer PB2 applies the double-verify voltage at voltage V2 to the second bit line BL2 during a second time period tdp2 between the fourth time tp4 and the fifth time tp5. The first time period tdp1 is longer than the second time period tdp2.

The times tp1 to tp5 and the times tdp1 and tdp2 are described as an example, and the present disclosure is not limited to this example. The control logic circuit 130 or the timing controller 131 may control the peripheral circuit 120 to apply voltages to the word line or the bit lines at times other than the times tp1 to tp5. The time periods tdp1 and tdp2 may be between different times than the times described with reference to FIG. 8 and may have different lengths or time intervals.

The control logic circuit 130 or the timing controller 131 adjusts the lengths of the time periods tdp1 and tdpb during which the double-verify voltage is applied to the bit lines BL1 and BL2 to perform the double-verify program operation on memory cells MC1 and MC2 located at different distances from the row decoder 121 or the reference position RP.

Although FIG. 8 illustrates, as an example, adjusting the time periods tdp1 and tdp2 to perform the double-verify program operation on the memory cells MC1 and MC2, the present disclosure is not limited to this example. For example, the control logic circuit 130 or the timing controller 131 adjusts a third time period to be shorter than the time periods tdp1 and tdp2, during which third time period the double-verify program operation is performed on the third memory cell positioned farther from the row decoder 121 or the reference position RP than the memory cells MC1 and MC2 are located.

The control logic circuit 130 or the timing controller 131 may adjust the length of the time period during which the double-verify voltage is applied to each memory cell, such as the memory cell MC1 or MC2 and may adjust the length of the time period during which the double-verify voltage is applied to the memory cell group, such as the memory cell group GR1 or GR2, that includes each memory cell. For example, the time period during which the double-verify voltage is applied to the first memory cell group GR1 within the third distance r3 from the row decoder 121 or the reference position RP is adjusted to the first time period tdp1, and the time period during which the double-verify voltage is applied to the second memory cell group GR2 positioned at a distance greater than the third distance r3 from the row decoder 121 or the reference position RP is adjusted to be the second time period tdp2.

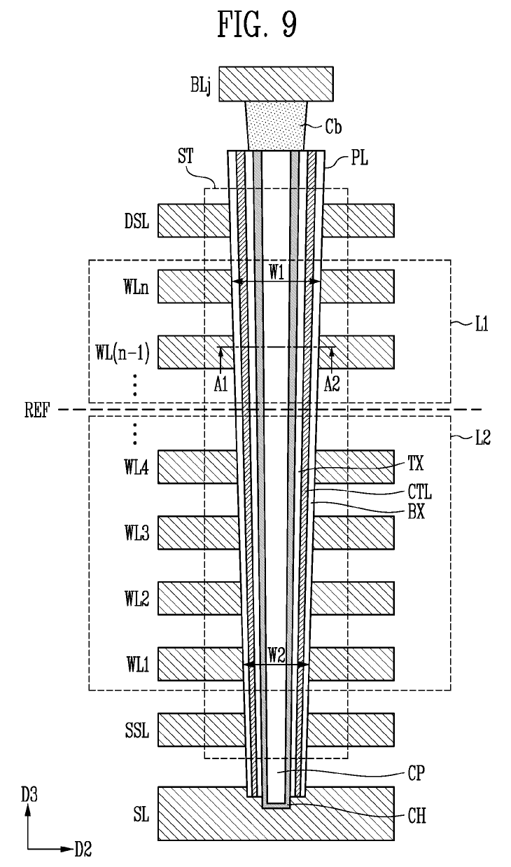

FIG. 9 is a diagram of a structure of a memory device according to an embodiment of the present disclosure. Referring to FIG. 9, a memory cell array is implemented in a three-dimensional structure in which memory cells are stacked vertically over a substrate. The string ST includes the source select line SSL, the plurality of word lines WL1 to WLn, a drain select line DSL stacked spaced apart, and a plug PL passing through the source select line SSL, the plurality of word lines WL1 to WLn, and the drain select line DSL. The source select line SSL, the plurality of word lines WL1 to WLn, and the drain select line DSL may include a metallic material such as tungsten (W), molybdenum (Mo), cobalt (Co), or nickel (Ni), or various materials such as silicon (Si) or polysilicon (Poly-Si). The plug PL extends in the third direction D3 between the source line SL and the jth bit line BLj.

The plug PL includes a core pillar CP, a channel layer CH, a tunnel isolation layer TX, a charge trap layer CTL, and a blocking layer BX. The core pillar CP may have a cylindrical, truncated conical, rectangular prism, or prismatic shape and may include an insulating material or a conductive material. The channel layer CH surrounds the core pillar CP and may include polysilicon. The tunnel isolation layer TX surrounds the channel layer CH and may be an oxide layer. The charge trap layer CTL surrounds the tunnel isolation layer TX and may be a nitride layer. The blocking layer BX surrounds the charge trap layer CTL and may be an oxide layer. A lower end of the channel layer CH contacts the source line SL, and an upper end of the channel layer CH contacts a bit line contact Cb. The bit line contact Cb is positioned between the jth bit line BLj and the plug PL.

The plug PL extends in the third direction D3 and have a width that varies with height due to the nature of the manufacturing process. For example, the width of an upper end of the plug PL is greater than the width of a lower end of the plug PL, thus the width of the plug PL decreases in a direction from the upper end toward the lower end. For example, among the word lines WL1 to WLn coupled to the string ST, when the first word line WL1 is positioned at the lowermost end, the nth word line WLn is positioned at the uppermost end, and the end of the plug PL contacting the nth word line WLn has a first width W1, the end of the plug PL contacting the first word line WL1 has a second width W2 smaller than the first width W1.

In an embodiment, the nth word line WLn contacting the end of the plug PL having the first width W1 and the first word line WL1 contacting the end having the second width W2 may have different lengths. The word lines WL1 to WLn each have different lengths. Thus, the word lines WL1 to WLn each have different resistance values.

For example, the word lines WL1 to WLn may be categorized as one of a first level L1 and a second level L2 based on a reference line REF. For example, the word lines WL1 to WL4 may be categorized as second level L2, and the word lines WL5 to WLn may be categorized as the first level L1. The word lines of the second level L2 have greater lengths and greater resistance than the word lines of the first level L1.

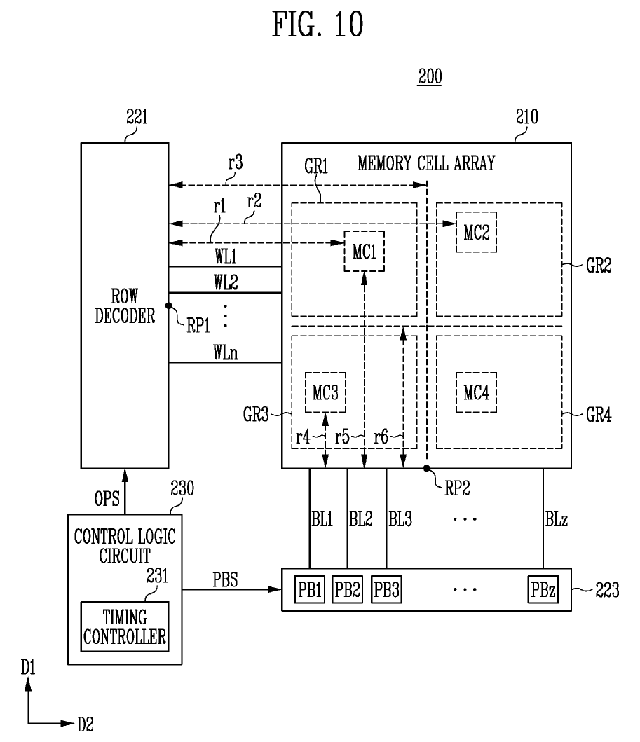

FIG. 10 is a diagram of memory cells coupled to different word lines and positioned at different distances from a reference position according to an embodiment of the present disclosure. Referring to FIGS. 2, 9, and 10, the memory cell array 110 includes a plurality of memory cells, including the memory cells MC1 to MC4. Memory device 200 is similar to the memory device 100 of FIG. 4.

In an embodiment, a memory cell array 210 includes the memory cells MC1 to MC4 coupled to word lines having different resistance values.

For example, when the same word line, such as the first word line WL1, couples the memory cells MC1 and MC2 and a row decoder 221, the resistance value of the word line between the first memory cell MC1 and the row decoder 221 and the resistance value of the word line between the second memory cell MC2 and the row decoder 221 are different. Because the second memory cell MC2 is positioned farther in the second direction D2 from the row decoder 221 or a first reference position RP1 than the first memory cell MC1, thus the second distance r2 is greater than the first distance r1, the resistance value of the word line between the second memory cell MC2 and the row decoder 221 is greater than the resistance value of the word line between the first memory cell MC1 and the row decoder 221.

For example, the memory cells MC1 and MC3 coupled to the same bit line, such as the first bit line BL1, are coupled to word lines having different resistance values, such as the first and nth word lines WL1 and WLn.

As described with reference to FIG. 9, the memory cell array 210 is implemented in a three-dimensional structure in which memory cells are stacked vertically over a substrate. The first to nth word lines WL1 to WLn coupling the memory cells of the memory cell array 210 and the row decoder 221 have different lengths and resistance values. Thus, the memory cells coupled to the first to nth word lines WL1 to WLn receive the operating voltage Vop through the word lines having different resistance values depending on the distance, such as distances r4 to r6, from the bottom of the plug PL or from a second reference position RP2.

Because the first memory cell MC1 is positioned farther in the first direction D1 from the second reference position RP2 than the third memory cell MC3 is positioned from the second reference position RP2, thus the fifth distance r5 is greater than the fourth distance r4, the word line WL1 to which the first memory cell MCb is coupled has a smaller resistance value than the word line WLn to which the third memory cell MC3 is coupled.

To prevent or mitigate the described problems, the memory device 100 according to an embodiment performs sensing operations or double-verify program operations on the memory cells such as memory cells MC1 and MC2 or memory cell groups such as memory cell groups GR1 and GR2 during time periods having different lengths.

The memory cells MC1 to MC4 are described as an example, and the memory cell array 210 may include other memory cells positioned at distances other than the distances r1, r2, r4, and r5 from the reference positions RP1 and RP2.

In an embodiment, the memory cell array 210 includes memory cell groups GR1 to GR4. The first memory cell group GR1 includes the first memory cell MC1 and a plurality of memory cells and is positioned within the third distance r3 in the second direction D2 from the first reference position RP1 and at a distance greater than the sixth distance r6 in the first direction D1 from the second reference position RP2.

The second memory cell group GR2 includes the second memory cell MC2 and a plurality of memory cells and is positioned at a distance greater than the third distance r3 in the second direction D2 from the first reference position RP1 and at a distance greater than the sixth distance r6 in the first direction D1 from the second reference position RP2.

The third memory cell group GR3 includes the third memory cell MC3 and a plurality of memory cells and is positioned within the third distance r3 in the second direction D2 from the first reference position RP1 and within the sixth distance r6 in the first direction D1 from the second reference position RP2.

The fourth memory cell group GR4 includes the fourth memory cell MC4 and a plurality of memory cells and is positioned at a distance greater than the third distance r3 in the second direction D2 from the first reference position RP1 and within the sixth distance r6 in the first direction D1 from the second reference position RP2.

The bit lines coupled to each of the memory cell groups GR1 to GR4 correspond to a first bit line group to a fourth bit line group, respectively.

A timing controller 231 adjusts times at which a page buffer circuit 223 senses voltages on the plurality of bit lines BL1 to BLz and/or applies double-verify voltages to the plurality of bit lines BL1 to BLz. The timing controller 231 adjusts a sensing time or double-verify time based on a position or distance from the reference positions RP1 and RP2 of the memory cell that is a target of a read operation or program operation.

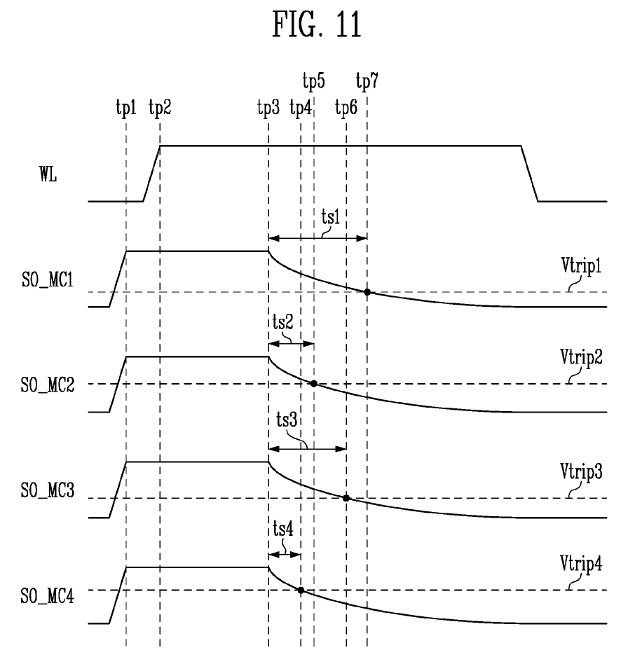

FIG. 11 is a timing diagram of a sensing operation according to an embodiment of the present disclosure. Referring to FIGS. 10 and 11, a control logic circuit 230 or the timing controller 231 adjusts the length of the sensing time of the first memory cells MC1 to differ from the length of the sensing time of the fourth memory cell MC4.

The memory cells MC1 to MC4 are positioned at different distances from the reference positions RP1 and RP2. For example, the first memory cell MC1 is positioned at the first distance r1 from the first reference position RP1 and at the fifth distance r5 from the second reference position RP2. The second memory cell MC2 may be positioned at the second distance r2 from the first reference position RP1 and at the fifth distance r5 from the second reference position RP2. The third memory cell MC3 may be positioned at the first distance r1 from the first reference position RP1 and at the fourth distance r4 from the second reference position RP2. The fourth memory cell MC4 is positioned at the second distance r2 from the first reference position RP1 and at the fourth distance r4 from the second reference location RP2.

In one or more embodiments, the first to fourth memory cells MC1 to MC4 may be coupled to word lines having different resistance values depending on their relative locations or positions. Thus, the fourth memory cell MC4, the second memory cell MC2, the third memory cell MC3, and the first memory cell MC1 sequentially receive a read voltage from the row decoder 221.

For example, the memory cells MC1 to MC4 are coupled to the page buffers PB1 to PB4 via the bit lines BL1 to BL4, respectively. The page buffers PB1 to PB4 each include sensing nodes SO_MC1 to SO_MC4.

At the first time tp1, the bit lines BL1 to BL4 are precharged, causing the voltage levels of the sensing nodes SO_MC1 to SO_MC4 to rise. After the bit lines BL1 to BL4 are precharged, the row decoder 221 transfers a read voltage to the word lines to which the memory cells MC1 to MC4 are coupled.

At the second time tp2, the read voltage is applied to the word lines. The memory cells MC1 to MC4 receive the read voltage at different times depending on the resistance values of the word lines.

In an embodiment, the page buffers PB1 to PB4 compare threshold voltages Vtrip1 to Vtrip4 having different values with the voltages sensed on the bit lines BL1 to BL4 or the voltages sensed on the memory cells MC1 to MC4.

The control logic circuit 230 or the timing controller 231 adjusts the lengths of the sensing time periods ts1 to ts4 of the memory cells MC1 to MC4 when the threshold voltages Vtrip1 to Vtrip4 having different values. For example, the control logic circuit 230 or the timing controller 231 adjusts the first sensing time period ts1 to be longer than the second sensing time ts2 when the first threshold voltage Vtrip1 is lower than the second threshold voltage Vtrip2.

At the third time tp3, the voltage levels of the first to fourth sensing nodes SO_MC1 to SO_MC4 begin to decrease as the bit lines BL1 to BL4 are discharged.

At the fourth time tp4 after the fourth sensing time period ts4 has elapsed from the third time tp3, the voltage of the fourth bit line BL4 is sensed, or the voltage of the fourth memory cell MC4 is sensed.

At the fifth time tp5 after the second sensing time ts2 has elapsed from the third time tp3, the voltage of the second bit line BL2 is sensed, or the voltage of the second memory cell MC2 is sensed.

At the sixth time tp6 after the third sensing time ts3 has elapsed from the third time tp3, the voltage of the third bit line BL3 is sensed, or the voltage of the third memory cell MC3 is sensed.

At a seventh time tp7 after the first sensing time ts1 has elapsed from the third time tp3, the voltage of the first bit line BL1 is sensed, or the voltage of the first memory cell MC1 is sensed.

The times tp1 to tp7 are described as an example, and the present disclosure is not limited to this example. The control logic circuit 230 or the timing controller 231 may control the row decoder 221 or the page buffer circuit 223 of FIG. 10 to apply voltages to the word lines or the bit lines at times other than the times tp1 to tp7.

The control logic circuit 230 or the timing controller 231 adjusts the lengths of the sensing times ts1 to ts4 to accurately sense the memory cells memory cells MC1 to MC4 at different distances from the reference positions RP1 and RP2.

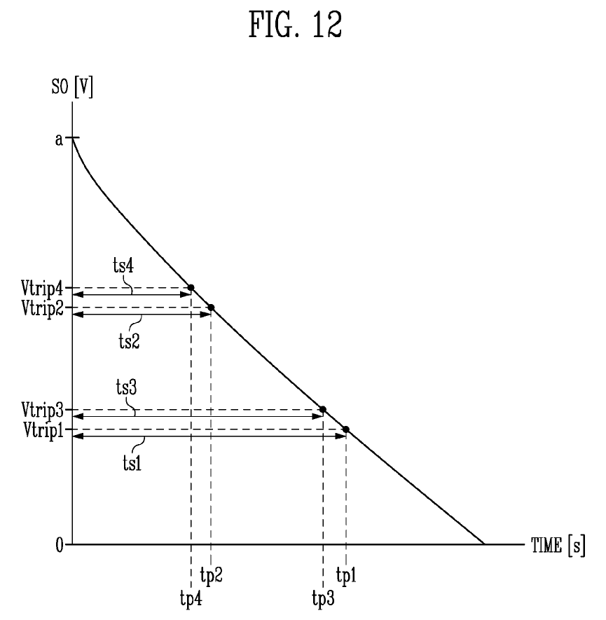

FIG. 12 is a timing diagram of threshold voltages according to an embodiment of the present disclosure. Referring to FIGS. 10 and 12, the page buffers PB1 to PB4 compare the threshold voltages Vtrip1 to Vtrip4 having different values with the voltages sensed on the bit lines BL1 to BL4.

The vertical axis of the graph indicates the voltage level at the sensing node SO, and the horizontal axis indicates the time after the time 0 at which the bit line is discharged for the sensing operation.

The page buffers PB1 to PB4 sense the voltages on the bit lines BL1 to BL4 and compare the sensed voltages with the threshold voltages Vtrip1 to Vtrip4, respectively, to read the data in the memory cells MC1 to MC4. The voltage levels of the threshold voltages Vtrip1 to Vtrip4 are different, although the speeds at which the bit lines BL1 to BL4 are discharged may be the same. Thus, the control logic circuit 230 or the timing controller 231 adjusts the lengths of the sensing time periods ts1 to ts4 such that the page buffers PB1 to PB4 may accurately read the data from the memory cells MC1 to MC4, respectively.

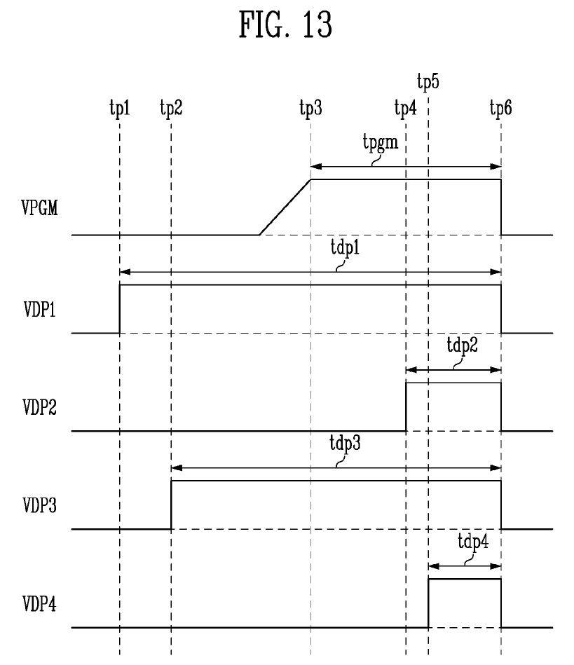

FIG. 13 is a timing diagram of a double-verify program operation according to an embodiment of the present disclosure. Referring to FIGS. 10 and 13, the control logic circuit 230 or the timing controller 231 adjusts the length of the double-verify program time periods of the first to fourth memory cells MC1 to MC4 to differ.

The page buffers PB1 to PB4 apply double-verify voltages to the bit lines BL1 to BL4 to which the memory cells MC1 to MC4 are coupled, respectively. For example, when the row decoder 221 transfers a program voltage via word lines to the memory cells MC1 to MC4, the page buffers PB1 to PB4 apply double-verify voltages to the bit lines BL1 to BL4 to which the memory cells MC1 to MC4 are coupled, respectively.

For example, the memory cells MC1 to MC4 are coupled to the page buffers PB1 to PB4 via the bit lines BL1 to BL4.

At the first time tp1, the first page buffer PB1 applies a double-verify voltage to the first bit line BL1.

At the second time tp2, the third page buffer PB3 applies a double-verify voltage to the third bit line BL3.

At the third time tp3, the row decoder 221 applies the program voltage VPGM to the memory cells MC1 to MC4 via the word lines.

At the fourth time tp4, the second page buffer PB2 applies a double-verify voltage to the second bit line BL2.

At the fifth time tp5, the fourth page buffer PB4 applies a double-verify voltage to the fourth bit line BL4.

The first page buffer PB1 applies a double-verify voltage to the first bit line BL1 during the first time period tdp1 between the first time tp1 and the sixth time tp6, the third page buffer PB3 applies a double-verify voltage to the third bit line BL3 during a third time period tdp3 between the second time tp2 and the sixth time tp6, the second page buffer PB2 applies a double-verify voltage to the second bit line BL2 during the second time period tdp2 between the fourth time tp4 and the sixth time tp6, and the fourth page buffer PB4 applies a double-verify voltage to the fourth bit line BL4 during a fourth time period tdp4 between the fifth time tp5 and the sixth time tp6.

The first time period tdp1 is longer than the third time period tdp3, and the second time period tdp2 is longer than the fourth time period tdp4. The memory cells MC1 and MC3 are positioned at the same or similar distances in the second direction D2 from the row decoder 221 or the first reference position RP1, and are positioned at different distances from the second reference position RP2. Accordingly, the resistance values of the word lines between the first memory cell MC1 and the row decoder 221 and between the third memory cell MC3 and the row decoder 221 are different.

The control logic circuit 230 or the timing controller 231 adjusts the lengths of the time periods tdp1 to tdp4 to minimize or reduce degradation of the reliability and durability of the memory device 200 that may be caused by delays or biases in the operating voltages, such as program or read voltages, caused by the different resistance values.

The times tp1 to tp6 and the time periods tdp1 to tdp4 as described with respect to FIG. 13 are provided as an example, and the present disclosure is not limited to this example. The control logic circuit 230 or the timing controller 231 may control the row decoder 221 or the page buffer circuit 223 of FIG. 10 to apply voltages to the word lines or the bit lines at times other than the times tp1 to tp6. The first to fourth time periods tdp1 to tdp4 may be between times other than those described with reference to FIG. 13 and may have different lengths.

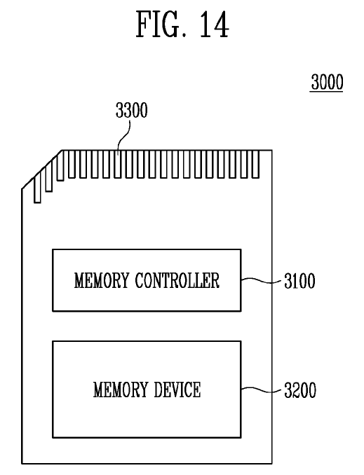

FIG. 14 is a block diagram of a memory card system 3000 including a storage device according to an embodiment of the present disclosure. Referring to FIG. 14, the memory card system 3000 includes a memory controller 3100, a memory device 3200, and a connector 3300.

The memory controller 3100 is coupled to the memory device 3200. The memory controller 3100 is configured to access the memory device 3200. For example, the memory controller 3100 is configured to control read, write, erase, and background operations of the memory device 3200. The memory controller 3100 is configured to provide an interface between the memory device 3200 and a host (not shown). The memory controller 3100 is configured to drive firmware for controlling the memory device 3200. The memory controller 3100 is formed similarly to the memory controller 11 described with reference to FIG. 1.

For example, the memory controller 3100 includes components such as Random Access Memory (RAM), a processing unit, a host interface, a memory interface, and an error correction circuit.

The memory controller 3100 communicates with an external device via connectors 3300. For example, the memory controller 3100 communicates with an external device, such as a host device, through at least one of various communication protocols such as a Universal Serial Bus (USB), a Multi-Media Card (MMC), an embedded MMC (eMMC), a Peripheral Component Interconnect (PCI), PCI-express (PCIe), Advanced Technology Attachment (ATA), Serial-ATA (SATA), Parallel-ATA (PATA), a Small Computer System Interface (SCSI), an Enhanced Small Disk Interface (ESDI), Integrated Drive Electronics (IDE), Firewire, Universal Flash Storage (UFS), Wi-Fi, Bluetooth, and/or Non-Volatile Memory express (NVMe). For example, the connector 3300 is configured according to at least one of these various communication protocols.

For example, the memory device 3200 is embodied as one of various non-volatile memory devices, such as Electrically Erasable and Programmable ROM (EEPROM), NAND flash memory, NOR flash memory, Phase-change RAM (PRAM), Resistive RAM (ReRAM), Ferroelectric RAM (FRAM), and/or Spin-Transfer Torque Magnetic RAM (STT-MRAM). The memory device 3200 may be similar to the memory device 100 described with reference to FIG. 1 or the memory device 200 described with reference to FIG. 10.

The memory controller 3100 and the memory device 3200 are integrated into a single semiconductor device to form a memory card. For example, the memory controller 3100 and the memory device 3200 may be integrated into a single semiconductor device to form a memory card, such as a Personal Computer Memory Card International Association (PCMCIA), a Compact Flash (CF) card, a smart media card (SM, SMC), a memory stick, a multimedia card (MMC, RS-MMC, MMCmicro), an SD card (SD, miniSD, microSD, SDHC), or Universal Flash Storage (UFS).

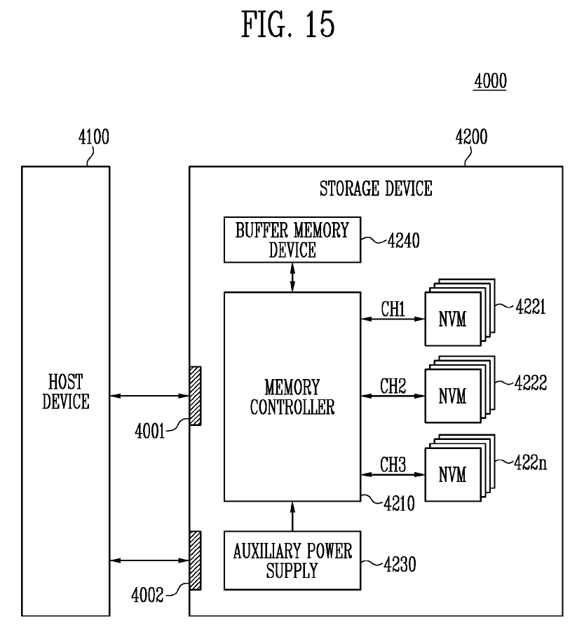

FIG. 15 is a block diagram of an electronic system 4000 according to an embodiment of the present disclosure. Referring to FIG. 15, the electronic system 4000 includes a host device 4100 and a storage device 4200. The storage device 4200 sends and receives signals to and from the host device 4100 via a signal connector 4001 and receives power via a power connector 4002. The storage device 4200 includes a memory controller 4210, a plurality of non-volatile memory devices 4221 to 422n, an auxiliary power supply 4230, and a buffer memory device 4240.

According to an embodiment of the present disclosure, the memory controller 4210 performs the functions of the memory controller 11 of FIG. 1.

The memory controller 4210 controls the plurality of non-volatile memory devices 4221 to 422n in response to signals received from the host device 4100. For example, the signals may be based on an interface of the host device 4100 and the storage device 4200. For example, the signals may be configured according to at least one communication standard or interface such as Universal Serial Bus (USB), Multi-Media Card (MMC), embedded MMC (eMMC), Peripheral Component Interconnect (PCI), PCI-express (PCI-e), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and Non-Volatile Memory express (NVMe) interfaces.

The auxiliary power supply 4230 is coupled to the host device 4100 via the power connector 4002. The auxiliary power supply 4230 receives a power voltage from the host device 4100 and may be charged. The auxiliary power supply 4230 provides a power voltage to the storage device 4200 when the power supply from the host device 4100 is not smooth or is not consistently provided. The auxiliary power supply 4230 is located within the storage device 4200 or located outside the storage device 4200. For example, the auxiliary power supply 4230 may be located on a main board and may provide auxiliary power to the storage device 4200.

The buffer memory device 4240 may operate as buffer memory for the storage device 4200. For example, the buffer memory device 4240 temporarily stores data received from the host device 4100 or data received from the plurality of non-volatile memory devices 4221 to 422n, or temporarily stores metadata of the plurality from non-volatile memory devices 4221 to 422n. The buffer memory device 4240 may include volatile memory, such as DRAM, SDRAM, DDR SDRAM, or LPDDR SDRAM, or non-volatile memory, such as FRAM, ReRAM, STT-MRAM, or PRAM.

According to the present disclosure, a memory device performs a sensing operation and a double-verify program operation and a storage device including the memory device are described.

A memory device capable of improving the reliability and durability by adjusting a sensing time and a double-verify program time depending on a position of a memory cell, and a storage device including the memory device are described.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a memory cell array including a first memory cell coupled to a first bit line extending in a first direction and a second memory cell coupled to a second bit line extending in the first direction;
a peripheral circuit including a first page buffer coupled to the first memory cell via the first bit line and a second page buffer coupled to the second memory cell via the second bit line; and
a control logic circuit configured to control the peripheral circuit;
wherein the second memory cell is positioned farther from a reference position than the first memory cell in a second direction perpendicular to the first direction; and
wherein the first page buffer is configured to perform one of a sensing operation and a double-verify program operation on the first memory cell during a first time period, and the second page buffer is configured to perform one of a sensing operation and a double-verify program operation on the second memory cell during a second time period that has a different length than the first time period.

2. The memory device of claim 1, wherein the first page buffer senses the first bit line at a second time after a first time period elapsed from a first time at which the first bit line is precharged;
wherein the second page buffer senses the second bit line at a fourth time after a second time period elapsed from a third time at which the second bit line is precharged; and
wherein the first time period is longer than the second time period.

3. The memory device of claim 2, wherein the first page buffer includes a first switch coupled between the first bit line and a first common sensing node, and a second switch coupled between the first common sensing node and a first sensing node;
wherein the second page buffer includes a third switch coupled between the second bit line and a second common sensing node, and a fourth switch coupled between the second common sensing node and a second sensing node; and
wherein the control logic circuit:
turns on the first switch and the second switch at the second time to sense the first bit line; and
turns on the third switch and the fourth switch at the fourth time to sense the second bit line.

4. The memory device of claim 2, wherein the first page buffer reads data by comparing a first voltage sensed on the first bit line with a first threshold voltage, and the second page buffer reads data by comparing a second voltage sensed on the second bit line with a second threshold voltage; and
wherein the second threshold voltage is higher than the first threshold voltage.

5. The memory device of claim 2, wherein the first memory cell and the second memory cell are coupled to a word line; and
wherein the peripheral circuit includes a row decoder configured to apply a read voltage to the word line at a time between the first time and the second time.

6. The memory device of claim 2, wherein the memory cell array comprises:
a first memory cell group, including the first memory cell, positioned within a first distance from the reference position in the second direction; and
a second memory cell group, including the second memory cell, positioned at a distance greater than the first distance from the reference position in the second direction; and
wherein the peripheral circuit is configured to sense, at the second time, a first bit line group to which the first memory cell group is coupled, and to sense, at the fourth time, a second bit line group to which the second memory cell group is coupled.

7. The memory device of claim 2, wherein the memory cell array includes a third memory cell coupled to a third bit line that extends in the first direction and positioned farther from the reference position than the second memory cell in the second direction;
wherein the peripheral circuit includes a third page buffer coupled to the third memory cell via the third bit line;
wherein the third page buffer senses the third bit line at a sixth time after a third time period elapsed from a third time at which the third bit line is precharged; and
wherein the third time period is shorter than the second time period.

8. The memory device of claim 1, wherein the peripheral circuit includes a row decoder configured to apply a program voltage to a word line coupled to the first memory cell and the second memory cells;
wherein the first page buffer is configured to apply a double-verify voltage to the first bit line from a first time to a second time after a first time period elapsed from the first time;
wherein the second page buffer is configured to apply the double-verify voltage to the second bit line from a third time to a fourth time after a second time period elapsed from the third time; and
wherein the first time period is longer than the second time period.

9. The memory device of claim 8, wherein the first page buffer includes a first switch coupled between the first bit line and a first common sensing node, and a second switch coupled between the first common sensing node and a first sensing node;
wherein the second page buffer includes a third switch coupled between the second bit line and a second common sensing node, and a fourth switch coupled between the second common sensing node and a second sensing node; and
wherein the control logic circuit:
turns on the first switch and the second switch from the first time to the second time to apply the double-verify voltage to the first bit line; and
turns on the third switch and the fourth switch from the third time to the fourth time to apply the double-verify voltage to the second bit line.

10. The memory device of claim 9, wherein the row decoder is configured to apply the program voltage to the word line from a fifth time to a sixth time; and
wherein the second time and the fourth time each precede the sixth time or are simultaneous with the sixth time.

11. The memory device of claim 8, wherein the row decoder is configured to apply an inhibit voltage to unselected bit lines; and
wherein the double-verify voltage is smaller than the inhibit voltage.

12. The memory device of claim 8, wherein the memory cell array comprises:
a first memory cell group including the first memory cell and positioned within a first distance from the reference position in the second direction; and
a second memory cell group including the second memory cell and positioned at a distance greater than the first distance from the reference position in the second direction; and
wherein the peripheral circuit is configured to apply the double-verify voltage to a first bit line group during the first time period and to apply the double-verify voltage to a second bit line group during the second time period.

13. The memory device of claim 8, wherein the memory cell array includes a third memory cell coupled to a third bit line that extends in the first direction and is positioned farther from the reference position in the second direction than the second memory cell is positioned;
wherein the peripheral circuit includes a third page buffer coupled to the third memory cell via the third bit line;
wherein the third page buffer is configured to apply the double-verify voltage to the third bit line from a fifth time to a sixth time after a third time period elapsed from the fifth time; and
wherein the third time period is shorter than the second time period.

14. The memory device of claim 1, wherein the reference position is on one surface of a row decoder within the peripheral circuit.

15. A memory device comprising:
a memory cell array including a first memory cell and a third memory cell coupled to a first bit line extending in a first direction, and a second memory cell and a fourth memory cell coupled to a second bit line extending in the first direction, the first memory cell and the second memory cell coupled to a first word line extending in a second direction perpendicular to the first direction, the third memory cell and the fourth memory cell coupled to a second word line extending in the second direction;
a peripheral circuit including a first page buffer coupled to the first memory cell and the third memory cell via the first bit line, and a second page buffer coupled to the second memory cell and the fourth memory cell via the second bit line; and
a control logic circuit configured to control the peripheral circuit;
wherein the second memory cell and the fourth memory cell are positioned farther from a first reference position in the second direction than the first memory cell and the third memory cell are positioned relative to the first reference position in the second direction;
wherein the first memory cell and the second memory cell are positioned farther from a second reference position in the first direction than the third memory cell and the fourth memory cell are positioned relative to the second reference position in the first direction; and
wherein the first page buffer and the second page buffer are configured to perform one of a sensing operation and a double-verify program operation on the first memory cell, the second memory cell, the third memory cell, and the fourth memory cell during one of a plurality of time periods, each time period having a different length.

16. The memory device of claim 15, wherein the first page buffer is configured to sense the first bit line at a second time after a first time period elapsed from a first time, at which time the first bit line is precharged, to read data from the first memory cell, and configured to sense the first bit line at a third time after a third time period elapsed from the first time to read data from the third memory cell;
wherein the second page buffer is configured to sense the second bit line at a fifth time after a second time period elapsed from a fourth time, at which time the second bit line is precharged, to read data from the second memory cell, and configured to sense the second bit line at a sixth time after a fourth time period elapsed from the fourth time, to read data from the fourth memory cell;
wherein the first time period is longer than the second time period, and the third time period is longer than the fourth time period; and
wherein the first time period is longer than the third time period, and the second time periods is longer than the fourth time period.

17. The memory device of claim 15, wherein the peripheral circuit includes a row decoder configured to apply program voltages to the first word line and the second word line;
wherein the first page buffer is configured to apply a double-verify voltage to the first bit line from a first time to a second time after a first time period elapsed from the first time for the first memory cell, and configured to apply the double-verify voltage to the first bit line from a third time to a fourth time after a third time period elapsed from the third time for the third memory cell;
wherein the second page buffer is configured to apply the double-verify voltage to the second bit line from a fifth time to a sixth time after a second time period elapsed from the fifth time for the second memory cell, and configured to apply the double-verify voltage to the second bit line from a seventh time to an eighth time after a fourth time period elapsed from the eighth time for the fourth memory cell;
wherein the first time period is longer than the second time period, and the third time period is longer than the fourth time period; and
wherein the first time period is longer than the third time period, and the second time period is longer than the fourth time period.

18. A storage device comprising:
a memory device configured to perform a read operation and a program operation; and
a memory controller configured to control the memory device;
wherein the memory device comprises:
a memory cell array including a first memory cell coupled to first bit line extending in a first direction and a second memory cell coupled to a second bit line extending in the first direction;
a peripheral circuit including a first page buffer coupled to the first memory cell via the first bit line and a second page buffer coupled to the second memory cell via the second bit line; and
a control logic circuit configured to control the peripheral circuit;
wherein the second memory cell is positioned farther from a reference position in a second direction perpendicular to the first direction than the first memory cell is positioned relative to the reference position in the second direction; and
wherein the first page buffer and the second page buffer are configured to perform one of a sensing operation and a double-verify program operation on the first memory cell and the second memory cell during one of a plurality of time periods, each time period having a different length.

19. The storage device of claim 18, wherein the first page buffer senses the first bit line at a second time after a first time period elapsed from a first time at which the first bit line is precharged;
wherein the second page buffer senses the second bit line at a fourth time after a second time period elapsed from a third time at which the second bit line is precharged; and
wherein the first time period is longer than the second time period.

20. The storage device of claim 18, wherein the peripheral circuit includes a row decoder configured to apply a program voltage to a word line coupled to the first memory cell and the second memory cell;
wherein the first page buffer is configured to apply a double-verify voltage to the first bit line from a first time to a second time after a first time period elapsed from the first time;
wherein the second page buffer is configured to apply the double-verify voltage to the second bit line from a third time to a fourth time after a second time period elapsed from the third time; and
wherein the first time period is longer than the second time period.
